(19) United States
(12) Patent Application Publication
(10) Pub. No.: US 2013/0133936 A1
(43) Pub. Date: May 30, 2013

(54) Bonded Board and Manufacturing Method Thereof

(71) Applicant: Hitachi, Ltd., Tokyo (JP)

(72) Inventors: Chiko YORITA, Fujisawa-shi (JP); Takashi KATANO, Yokohama-shi (JP); Takayuki ONO, Hadano-shi (JP); Yoshimasa TASHIRO, Isehara-shi (JP); Yuichi SEKINO, Hadano-shi (JP); Masami ONO, Inagi-shi (JP); Tsutomu SAKAMOTO, Hadano-shi (JP); Hiroyuki DOI, Odawara-shi (JP); Shinichi FUJIWARA, Yokohama-shi (JP)

(73) Assignee: HITACHI, LTD., Tokyo (JP)

(21) Appl. No.: 13/687,734

(22) Filed: Nov. 28, 2012

(30) Foreign Application Priority Data
Nov. 29, 2011 (JP) 2011-260467
Jul. 5, 2012 (JP) 2012-151288

(51) Int. Cl. H05K 1/09; B23K 31/02

(52) U.S. Cl. CPC H05K 1/09; B23K 31/02
USPC 174/257; 156/285; 228/175

(57) ABSTRACT

Provided is an integral thermal compression bonded board technology which is high in reliability and low in cost. In a process of bonding printed boards to each other, electrodes are connected with each other by solder connection using a Cu core solder plated ball and the boards are bonded by a three-layer bonding material constituted by a bonding material layer, a ball maintaining core layer, and the bonding layer, and solder of the Cu core solder plated ball inserted into holes of three layers is formed by integral thermal compression. They are connected with each other by flux or welcoming solder.

### CLAIM OF PRIORITY

The present application claims priority from Japanese application serial no. JP2011-260467, filed on Nov. 29, 2011, and Japanese application serial no. JP2012-151288, filed on Jul. 5, 2012, the content of which is hereby incorporated by reference into this application.

### BACKGROUND OF THE INVENTION

1. Field of the Invention

The present invention relates to an electronic apparatus that connects LSIs to each other by board wirings to transmit an electric signal, and particularly, to a connection technique of board wirings of an electronic apparatus that transmits a high-speed electric signal by using board wiring of a printed board.

2. Description of the Related Art

In recent years, with spreading of the Internet or improvement of a band by asymmetric digital subscriber line (ADSL), fiber to the home (FTTH), and the like, information processing devices such as a router, a server, a RAID, and the like have been becoming a large capacity to double for three years, a transmission rate of a backplane has also been actualized as 5 Gbps, and it is anticipated that the transmission rate reaches 10 Gbps in a next generation. As a result, high densification of the servers and high-transmission handling of a midplane in a rack are an urgent need and there is a large request for high-density deployment of a blade connected to a midplane of a next production server by a press-fit connector.

Herein, a schematic diagram of an apparatus to which a signal is intertransmitted through the midplane in a server housing is illustrated in FIG. 1. For example, a server blade 13 is connected onto the surface of the midplane and a service processor (SVP) 14, a switch module (SW), a fan module (FAN), and a power supply unit (PSU) are connected onto a rear surface thereof. The midplane 10 has a structure in which a spring-type pin of a press-fit connector 15 that is drawn out from the device 13 is inserted into a through-hole 11 (hereinafter, referred to as a through-hole TH) of the midplane 10, for example, on a multilayered printed board constituted by 24 layers in electrical connection with each device. In the structure in the related art, since the pin inserted from one side occupies one through-hole TH, the press-fit connectors were not overlapped with each other. However, with an increase in the type of the press-fit connector of the blade and a tendency of high-density mounting of the blade, there is a request for free placement capable of placing the press-fit connector from both surfaces of the midplane.

With respect to the request, development of a two-surface bonding board technology capable of selecting electrical connection at a predetermined position by bonding multilayered boards having the through-holes TH is the urgent need. In order to form a two-surface press-fit connection board by a printed board forming process in the related art, a PCB process is repeated, and as a result, a cost is high. As an inter-electrode connection method for establishing a low-cost integrated lamination process, Ag paste printing or a method of printing pastes of Sn and Ag in a wiring part and integrally connecting the pastes of Sn and Ag to the wiring part is used. In this regard, a method of connecting electrodes with each other by using a Cu core ball is disclosed in Japanese Patent Application Laid-Open Publication No. 2010-067623, Japanese Patent Application Laid-Open Publication No. 2003-174254, and Japanese Patent Application Laid-Open Publication No. 2007-273982.

For example, in Japanese Patent Application Laid-Open Publication No. 2010-067623, on a chip-embedded board having a structure in which a plurality of boards including a board mounted with a semiconductor chip are laminated, a ball of a Cu core is used as an electrical connection member of the plurality of boards and when a connection terminal of the board and the ball are bonded with each other, electrical and mechanical connectors are formed by melting a coating layer of the ball. An example is disclosed, in which the Cu core ball serves an external connection terminal while maintaining intervals of the connected boards to a predetermined value.

Further, Japanese Patent Application Laid-Open Publication No. 2003-174254 discloses an example of adopting a Cu ball covered with an alloy film as a solder method capable of acquiring stable bonding reliability within a heat-resistant security temperature of an electronic component by using a Pb-free solder instead of the Sn—Pb based solder in the related art when semiconductor packages such as BGA, QFP, and the like are soldered to a glass epoxy circuit board, and the like. This method is a solder method in which an intermetal compound layer is formed when the Pb-free solder containing Sn and Zn used in a solder paste printed on a wiring film on the circuit board and the Cu ball bonded to the electrode of the semiconductor package are bonded to each other, in a reflow furnace.

In addition, Japanese Patent Application Laid-Open Publication No. 2007-273982 proposes a solder connection method using a metallic ball such as Cu, Ag, Au balls and the like or a ball in which Au is plated on Al, and the like as a new solder connecting method equivalent to a high-temperature based Pb-free solder in a process of temperature hierarchy connection by a solder used in the semiconductor device and a solder used to connect the semiconductor device itself to the board. The embodiment discloses an example of enabling connection which is resistant to a reflow in connection with an electrode of a relay board by evaporating, plating, pasting Sn on a thin-film electrode of an Si chip side, providing a paste and the like which are formed by combining the metallic ball and the solder ball, thermally compressing the metallic balls of Cu, Ag, Au, and the like thereon, and forming a contact portion with thin-film electrode materials (Cu, Ni, Ag, and the like) and an intermetal compound with Sn therearound, in examples of BGA and CSP.

A first object is as follows. A bonding body formed by coating the Cu core materials of Japanese Patent Application Laid-Open Publication No. 2010-067623, Japanese Patent Application Laid-Open Publication No. 2003-174254, and Japanese Patent Application Laid-Open Publication No. 2007-273982 with the solder is a consumer product and the sizes of a housing and a circuit are also small. Therefore, there is a high request for high densification in terms of both the entire device, and components and boards. Accordingly, in a wiring structure of the board, a signal or power is primarily transmitted through a V via-hole of a build-up board in which higher-density wiring can be achieved as well as through the through-hole penetrating the board. Contrary to this, since industrial servers or control devices have large-sized housings and circuits, boards thereof are also large-sized and multilayered. Therefore, since the board itself is expensive, the wiring structure of transmitting the signal or power through the through-hole is used for wiring forming.

For example, a multilayered board called the backplane (midplane) in which the blade of the server is stuck is positioned at the center of the housing and this board also transmits and receives the signal/power through the through-hole. In this case, the press-fit connector for receiving the electrical signal transmitted from the blade is used as the through-hole of the backplane (midplane). In the structure of the backplane (midplane) in the related art, the press-fit pin of the press-fit connector is inserted into the through-hole to transmit and receive the signal/power. In this case, one press-fit pin is inserted into one through-hole from one side.

However, in order to cope with the high densification of the server or diversification of pin intervals of the press-fit connector, the appropriative connection structure in which one press-fit pin is inserted into to exclusively occupy one through-hole from one side like the structure in the related art has a limit in the number of blades stored in the housing by.

A second object is as follows. Since the electrical signal of the server, and the like are faster and the signal is fully reflected at an opened through-hole end and returns to a branch point, a (spare) through-hole wiring through which the signal does not pass, which is called a stub deteriorates signal quality. Therefore, a method of removing a through-hole Cu plated part that does not serve as a route of the signal input from the press-fit pin from the rear surface of the board with a drill, which is called a back drill, is adopted in the related art. By this method, the quality of a high-speed transmission signal is secured, but a large cost is also caused.

A third object is as follows. After bonding the bonding body formed by coating the Cu core materials of Japanese Patent Application Laid-Open Publication No. 2010-067623, Japanese Patent Application Laid-Open Publication No. 2003-174254, and Japanese Patent Application Laid-Open Publication No. 2007-273982 with the solder, the solder remains. Further, in the semiconductor of Japanese Patent Application Laid-Open Publication No. 2010-067623, Japanese Patent Application Laid-Open Publication No. 2003-174254, and Japanese Patent Application Laid-Open Publication No. 2007-273982 or a small-sized board mounted with the semiconductor and modulated to an electronic component, for example, a board having 100 mm square or a long side of approximately 200 mm, there are positional deviation of materials by a difference in a contraction size by a thermal expansion coefficient of the materials when the board is contracted after the board is formed and a nonuniform height by distortion of the board, and it is expected that in a large-sized board (for example, a size of 500 mm×600 mm) such as the midplane, the boards are large, the position of the Cu core solder ball for electrode connection, which is placed in each electrode on a bonded board, deviates from the electrode of the board, or a failure in which the height is not reached occurs.

That is, in the large-sized board such as the midplane, and the like, for example, when wiring density is higher at the center than the periphery thereof, it is expected that the center of the board is inflated more than the periphery due to a difference in linear expansion coefficient between the materials such as the resin and the copper. In this case, nonuniformity may occur, in which a distance between electrodes of peripheries of upper and lower multilayered printed wiring boards which are bonding targets facing each other is increased.

Further, in order to maintain long-term reliability of a board bonding portion, a countermeasure of preventing stress from being concentrated on an end of a connection portion needs to be taken so that a connection shape of melted solder is a drum shape.

Therefore, it is an object of the present invention to provide a high-reliability and low-cost two-surface bonded board wiring that connects the board electrodes by the Cu core solder ball and bonds wiring boards at a low cost.

### SUMMARY OF THE INVENTION

According to an aspect of the present invention, in order to address the above problems, there is provided a manufacturing method of a bonded board including: mounting a first bonded board on a base with a surface thereof where an electrode is formed, facing the top; sequentially mounting a first bonding material layer and a core layer on the first bonded board with opened holes matched with the positions of the electrodes; putting and placing a Cu core solder plated ball coated with a predetermined thickness in the opened hole of the core layer one by one; mounting a second bonding material layer on the core layer with the opened hole matched with the position of the electrode; mounting a second bonded board at a position where the electrode formed on the first bonded board and an electrode of the second bonded board face each other with a surface where the electrode is formed, facing the bottom; and uniformly heating the first and second bonded boards, the first and second bonding material layers, the core layer, and the Cu core solder plated ball which are overlapped with each other and uniformly applying thrust to the entire second bonded board to integrally and thermally compress the first and second bonded boards, the first and second bonding material layers, the core layer, and the Cu core solder plated ball, under an environment in which the first and second bonded boards, the first and second bonding material layers, the core layer, and the Cu core solder plated ball are put in a vacuum thermal compression device to be subjected to vacuum processing.

According to another aspect of the present invention, in order to address the above problems, there is provided a manufacturing method of a bonded board including: applying solder paste to an electrode formed on a bonding surface of a first bonded board; putting and placing a Cu core solder plated ball coated with a predetermined thickness one by one in a hole opened on a mask mounted on the bonded board in each electrode of the first bonded board of each electrode of the first bonded board; connecting a Cu core ball and the electrode of the first bonded board by melting solder of the Cu core solder plated ball and solder paste applied to the electrode by reflow heating; mounting on the first bonded board a layer associated with bonding of three layers constituted by a core layer where a hole determining the position of the Cu core solder plated ball is formed, and first and second bonding material layers having holes formed at the same position and placed on both surfaces of the core layer, which bond the core layer and the bonded board, by passing the Cu core solder plated ball connected onto the electrode of the first bonded board through the hole; mounting a second bonded board at a position where the electrode formed on the first bonded board and an electrode of the second bonded board face each other with a surface where the electrode is formed, facing the bottom; and uniformly heating the first and second bonded boards, the first and second bonding material layers, the core layer, and the Cu core solder plated ball which are overlapped with each other and uniformly applying thrust to the entire second bonded board to integrally and thermally compress the first and second bonded boards, the first and second bonding material layers, the core layer, and the Cu core solder plated ball, under an environment in which the first and second bonded boards, the first and second bonding material layers, the core layer, and the Cu core solder plated ball are put in a vacuum thermal compression device to be subjected to vacuum processing.

Further, in order to address the above problems, in the manufacturing method of a bonded board, in the step of uniformly heating the first and second bonded boards, the first and second bonding material layers, the core layer, and the Cu core solder plated ball which are overlapped with each other and uniformly applying thrust to the entire second bonded board to integrally and thermally compress the first and second bonded boards, the first and second bonding material layers, the core layer, and the Cu core solder plated ball, under an environment in which the first and second bonded boards, the first and second bonding material layers, the core layer, and the Cu core solder plated ball are put in a vacuum thermal compression device to be subjected to vacuum processing, melted resins of the first and second bonding material layers flow into a hole space between the electrodes to cover a solder connection portion of the Cu core ball and a control of decreasing and maintaining the temperature in the device to a predetermined temperature or a second predetermined temperature is performed until reaching curing viscosity, by applying uniform thrust to the entire second bonded board, while maintaining the temperature at the predetermined temperature at the time when the temperature reaches the predetermined temperature which is higher than a melting point of solder by uniform heating under the vacuum processing environment.

According to yet another aspect of the present invention, in order to address the above problems, there is provided a bonded board including: a layer which is associated with bonding of a three-layer structure constituted by a core layer having a hole for determining the position of a Cu core solder plated ball for connecting electrodes to each other between both boards of a first bonded board where one or more electrodes are formed on a first surface and a second bonded board where one or more electrodes are formed on a second surface with corresponding electrodes facing each other, and a plurality of bonding material layers having holes formed at the same position and placed on both surfaces of the core layer, which bonds the core layer and the bonded board; and a Cu core solder plated ball placed between the electrodes one by one and the first surface of the first bonded board and the second surface of the second bonded board are bonded by an integral thermal-compression process, wherein the Cu core ball is connected with the respective corresponding electrodes of both the bonded boards by a drum-shaped bonding portion constituted by solder and an intermetal compound, and resins of the plurality of bonding material layers are melted by the integral thermal compression process and fills a void around the drum-shaped bonding portion constituted by the solder and the intermetal compound connecting the Cu core ball and each electrode to become a cured bonding material layer.

An effect which can be acquired by a representative invention among inventions disclosed in this application will be simply described below.

As the acquirable effect, a low-cost printed board having a solder connection shape with high reliability can be implemented by integrally and thermally compressing the board by using a bonding process of the board without positional deviation of the Cu core ball from the position of the electrode of the board. Since a core material for preventing the positional deviation can serve as a ball inserting jig, a low-cost board wiring can be implemented. Further, since the shape of a drum-shaped solder connection cross section reduces distortion caused due to deformation by a difference in thermal expansion coefficient accompanied by a temperature cycle of start/stop of the device, it is possible to provide an electrode connection portion-shaped board which has a structure with sufficiently high reliability and is excellent in a real actuation life-span.

Further, a stubless structure for improving a high-speed signal electrical transmission characteristic of the board can be prepared without back-drill processing.

From this point, a low-cost and high-reliability bonded board can be provided.

### BRIEF DESCRIPTION OF THE DRAWINGS

FIG. 1 is a diagram illustrating a schematic cross-sectional configuration of a part inserted with a press-fit pin of a server midplane structure in the related art;

FIG. 2 is a diagram illustrating a schematic cross-sectional configuration of a part inserted with a press-fit pin of a server midplane structure in the present invention;

FIG. 3 is a diagram describing a process of a manufacturing method of a bonded board of a first embodiment;

FIG. 4 is a diagram describing the process of a manufacturing method of the bonded board of the first embodiment;

FIG. 5 is a diagram illustrating an examination example of a solder plating thickness of a Cu core solder plated ball adopted in the manufacturing process of the bonded board of the first embodiment;

FIG. 6 is a diagram illustrating a control timing of a temperature, thrust, and a vacuum level in a vacuum thermal compression device of the first and a second embodiments;

FIG. 7 is a diagram illustrating a schematically configured cross section of the Cu core solder plated ball, three interlayer bonding material layers, and upper and lower printed boards constituting a bonding portion of the bonded board of the present invention;

FIG. 8 is a diagram describing a multilayered printed board bonding process of the second and a third embodiments;

FIG. 9 is a diagram illustrating a control timing of a temperature, thrust, and a vacuum level in a vacuum thermal compression device of the third embodiment;

FIG. 10 is a diagram illustrating a state in which a Cu core solder plated ball and an electrode of a lower multilayered printed board are connected to position an upper multilayered printed board;

FIG. 11 is a diagram illustrating a state in which solder paste and solder of the Cu core solder plated ball are melted and connected, and as a result, solder and an intermetal compound form a drum-shaped fillet between electrodes of the upper and lower multilayered printed wiring boards;

FIG. 12 is a diagram illustrating a state in which solder paste and solder of the Cu core solder plated ball are melted and connected, and as a result, solder and an intermetal compound form a drum-shaped fillet between electrodes of the upper and lower multilayered printed wiring boards; and

FIG. 13 is a diagram illustrating a state of the filet which the solder and the intermetal compound form between the electrodes of the upper and lower multilayered printed wiring boards when the amount of the solder paste is excessive.

### DESCRIPTION OF THE PREFERRED EMBODIMENTS

Hereinafter, embodiments of the present invention will be described in detail with reference to the accompanying drawings. Meanwhile, in all the drawings for describing the embodiments, the same reference numerals principally refer to the same components and a repeated description will be omitted.

### First Embodiment

First, the structure of a bonded board as a target in the embodiment will be described.

FIG. 1 illustrates a multilayered printed wiring plate called a midplane formed by a printed board forming process in the related art, which is connected with an inserted press-fit connect pin while a through-hole is plated with copper. In the multilayered printed wiring plate, stereoscopic connection is generally configured by only holes penetrating the plate, but buried vias which are installed in a part of a plate thickness, blind vias, or surface vias installed on some layers of the surface have been introduced in many cases in addition to the through-holes in order to increase wiring flexibility. Further, it is also considered that a build-up printed wiring plate in which a conductor layer and an insulating layer are laminated with the aforementioned multilayered printed wiring plate as a core part is also included in the target of the embodiment.

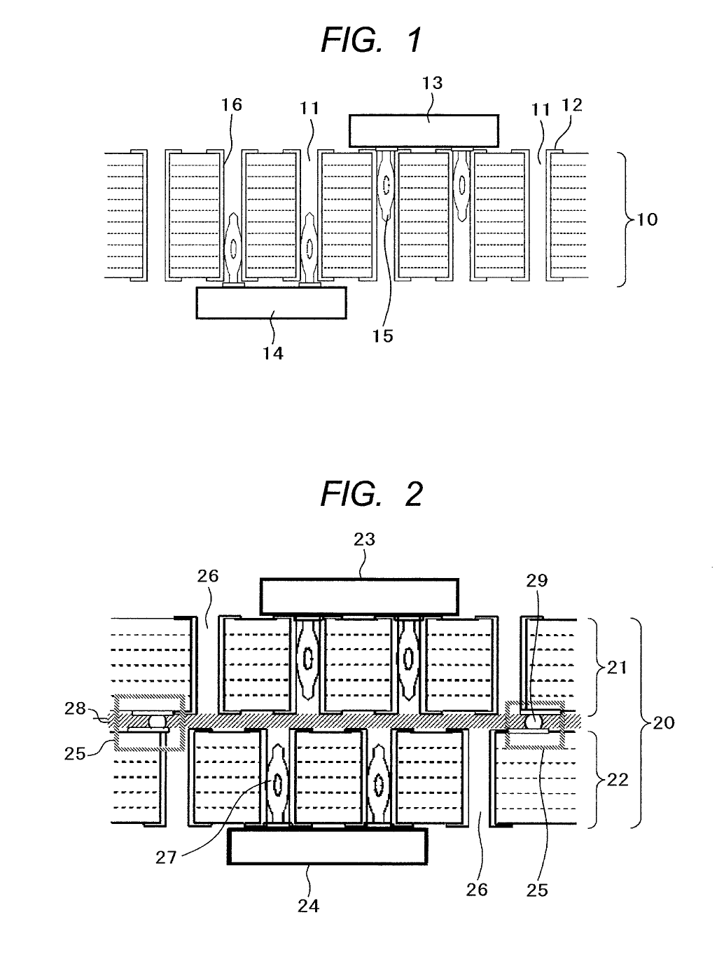

A first board 21 and a second board 22 with through-holes 26 are set as bonding targets and an electrode 25 for achieving electrical connection is formed to face a predetermined position on a bonding surface of each bonding target board. Further, a material 28 associated with bonding of the boards has a 3-layer structure of a bonding material layer, a core layer, and a bonding material layer, and the electrical connection of the electrodes 25 is performed by solder connection of a ‘Cu core solder plated ball’ 29 in which Ni plating 45 and solder plating 34 are formed in a layer shape around a metallic spherical body called a Cu core 35 to the electrode of each board. In addition, surfaces of the bonding target boards where signal connecting electrodes are formed face each other to be integrally laminated as illustrated in FIG. 2 to form a bonded board 20 by a vacuum thermal-compression process. In this case, the thickness of the material 28 associated with the bonding is selected so that the diameter of the Cu core ball 35 and the height of three layers of the bonding material layer, the core layer, and the bonding material layer of the material 28 associated with the bonding of the boards after bonding are substantially equivalent to each other. By this configuration, the Cu core ball is connected in an excellent shape without selective application of pressure to only the Cu core ball, that is, without deformation by pressure in board pressing.

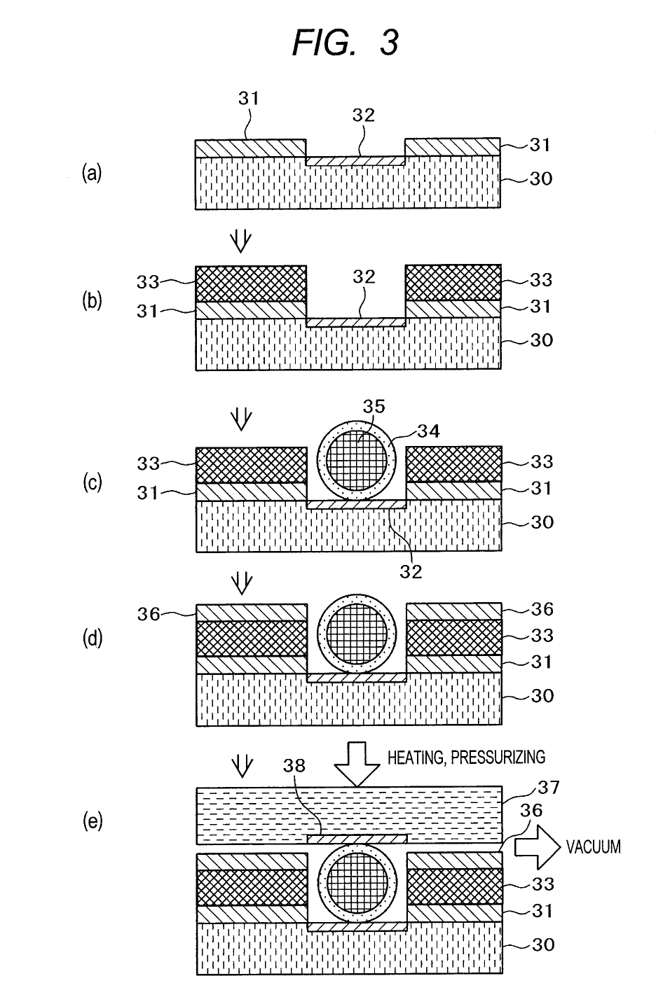

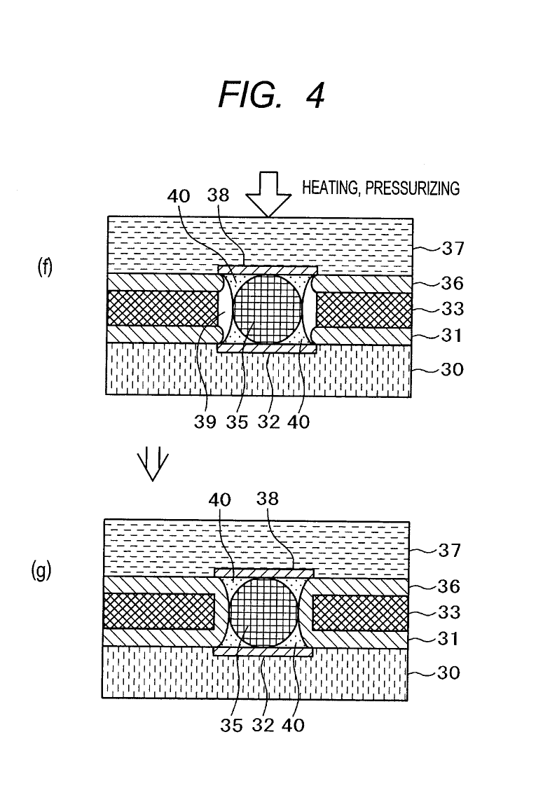

Subsequently, a manufacturing method of the bonded board of the embodiment will be described with reference to FIGS. 3 and 4.

First, in a process of FIG. 3A, the first board (multilayered printed board) 30 is mounted on a support of a stone where a temperature in a vacuum thermal-compression device is constant with a surface where a signal connecting copper electrode 32 is formed facing the top. A flux (not illustrated) is, in advance, applied onto each copper electrode 32 of the first board 30 by using a mask, and the like. Further, a first bonding material layer 31 is mounted on the first board 30 by being guided by a positioning pin (not illustrated), and the like. In the first bonding material layer 31, since the Cu core solder plated ball enters the position of the electrode 32 formed on the first board 30, one clearance, for example, a hole having approximately 10 μm is, in advance, formed by a drill or a laser. As the first bonding material layer 31, for example, a prepreg material (a material acquired by impregnating an epoxy resin, and the like in a glass fiber), and the like are used.

Subsequently, in a process of FIG. 3B, the core layer 33 is mounted on the first bonding material layer 31 by being guided by a positioning pin (not illustrated), and the like. Even in the core layer 33, since the Cu core solder plated ball enters the position of the electrode 32 formed on the first board 30, one clearance, for example, the hole having approximately 10 μm is, in advance, formed by the drill or the laser. As the core layer 33, for example, a C stage (a material containing the glass fiber in which a plastic material has been already cured), and the like are used.

Subsequently, in a process of FIG. 3C, the Cu core ball 35 subjected to the solder plating 34 is put into respective holes formed on the core layer 33 and is positioned. The Cu core solder plated ball has a diameter of approximately, for example, 200 μm and is formed by performing Ni plating of approximately 0.5 μm to 2 μm on the Cu core ball 35 and plating a solder (for example, a Sn-3Ag-0.5Cu solder) 34 having a thickness of approximately 5 μm to 50 μm thereon. The Cu core solder plated ball is moved on the core layer 33 by, for example, a brush, and the like to be put in each hole one by one and the remaining balls are recovered by being swept with the brush. The core layer 33 serves to prevent a horizontal position of the Cu core solder plated ball from deviating and fill a height-direction thickness of the Cu core ball and further, serves as a ball insertion jig for putting the Cu core solder plated ball in the electrode position. In this case, as a countermeasure of a point that the Cu core solder plated ball easily enters a clearance between the first board 30 and the first bonding material layer 31 or the core layer 33, adhesion holes are drilled on the first board 30 and the first bonding material layer 31, and the core layer 33 and the first bonding material layer 31 are attracted to be closely attached to the first board 30, although not illustrated.

Subsequently, in a process of FIG. 3D, a second bonding material layer 36 is mounted on the core layer 33 by being guided by a positioning pin (not illustrated), and the like. Even in the second bonding material layer 36, since the Cu core solder plated ball enters the position of the electrode 32 formed on the first board 30, one clearance, for example, the hole having approximately 10 μm is, in advance, formed by the drill or the laser. As the second bonding material layer 36, for example, the prepreg material, and the like are used similarly as the first bonding material layer 31.

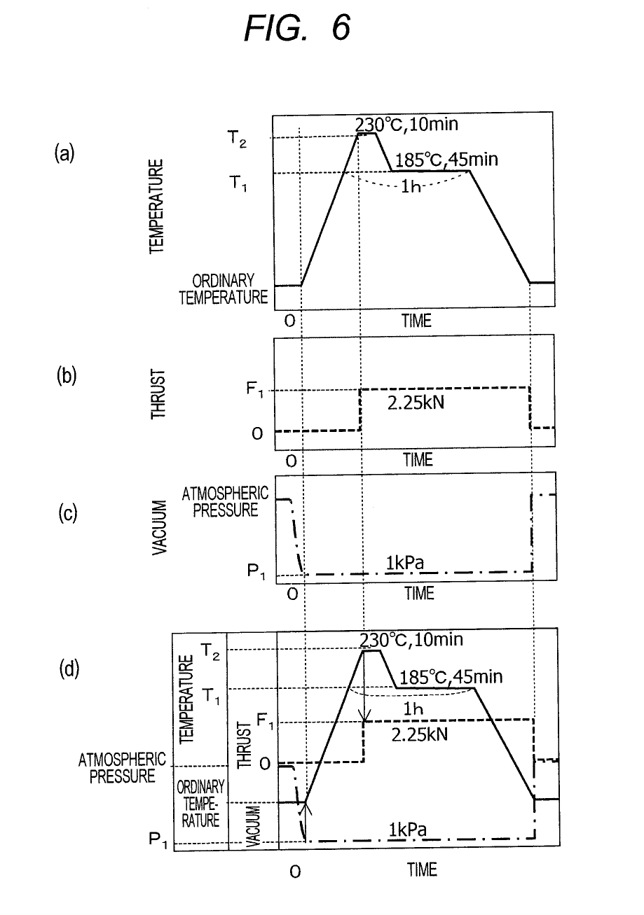

Subsequently, in a process of FIG. 3E, the second board (multilayered printed board) 37 is mounted by being guided by a positioning pin (not illustrated), and the like with a surface thereof where a copper electrode 38 is formed, facing the bottom. A flux (not illustrated) is applied onto each copper electrode 38 of the second board 37 by using the mask, and the like. The copper electrode 38 of the second board 37 is mounted while contacting the top of the Cu core solder plated ball. As illustrated in a profile of a control in FIG. 6, the vacuum thermal-compression device depressurizes the entire board up to, for example, 1 kPa (P₁) by performing vacuum processing of the entire board to suppress occurrence of a void by vacuum and uniformly heat the entire board. A melting point of the solder 34 of the solder ball is in the range of 217° C. to 230° C. in the case of, for example, the Sn-3Ag-0.5Cu solder and the solder 34 reaches the temperature, and as a result, the solder is melted to form an intermetal compound on a boundary portion with the copper electrode. In addition, when a heating temperature reaches, for example, 230° C. (T₂), thrust uniformly applied to the entirety of the upper second board 37 is applied at, for example, approximately 2.25 kN (F₁). In the control of heating, after 230° C. (T₂) is maintained for approximately 10 minutes, the temperature is decreased to reach 185° C. and thereafter, the temperature of approximately 185° C. (T₁) is maintained for 45 minutes (it may be regarded that resin curing of the first and second bonding material layers 31 and 36 is terminated). Thereafter, at the time when the temperature is gradually decreased up to an initial temperature, pressurizing and the vacuum processing are stopped to terminate the bonding processing of the board.

A progress during the heating and the pressurizing process in the vacuum thermal-compression device is illustrated in a process of FIG. 4F. The solder (for example, Sn-3Ag-0.5Cu solder) 34 plating the Cu core ball 35 starts being melted at the time when the temperature reaches 217° C. to 230° C., and as a result, the intermetal compound is formed at boundary portions of the melted solder and the copper electrodes 32 and 38. In the related art, it is known that largest distortion caused due to a difference in linear expansion coefficient between different materials is applied to an end of a connection portion between the solder ball and the electrode. Contrary to this, when the melted solder illustrated in FIG. 4F forms the intermetal compound with the copper electrode to form a drum-shaped fillet, it has been known, by a past finding and a simulation result, that stress applied to an end of the drum-shaped fillet is suppressed to be smaller than an end of a connection portion having a different shape. That is, a heat-resistant fatigue characteristic of a solder bonding portion may be the highest.

Accordingly, an object of the manufacturing method of the bonded board according to the embodiment is to control heating and pressurizing timings so that after the solder of the Cu core solder plated ball starts being melted, and as a result, the formed intermetal compound and a remaining solder form a fillet shape therebetween with the copper electrode and thereafter, the first bonding material layer 31 and the second bonding material layer 36 are melted to flow while filling a void 39 of a hole part, and the drum shapes of the intermetal compound and the solder may be maintained by the pressure of a resin that flows in.

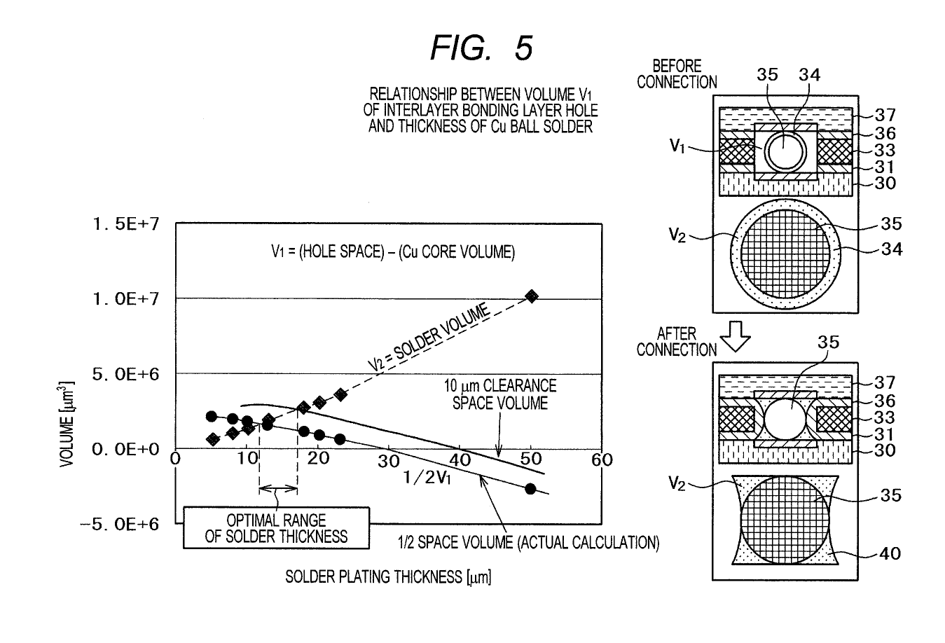

Further, calculation of the amount of the solder required so as for the intermetal compound and the solder to maintain the accurate drum shapes is a result illustrated in FIG. 5. An interlayer bonding material layer hole volume V1 is calculated by subtracting, from a hole space formed by combining hole parts formed in the first bonding material layer 31, the core layer 33, and the second bonding material layer 36, which are interposed between the first board 30 and the second board 37, the Cu core volume 35 of the Cu core solder plated ball received therein.

Interlayer bonding material layer hole volume V1=(hole space)−(Cu core volume) (Equation 1)

A solder volume V2 of the Cu core solder plated ball is calculated from a solder plating thickness. When the solder volume V2 of the Cu core solder plated ball is ½ of the interlayer bonding material layer hole volume V1, it may be verified by a test that the intermetal compound and the solder that are connected to both electrodes have an substantial optimal drum shape. Therefore, under a condition that the diameter of the drill that drills the holes on the first bonding material layer 31, the core layer 33, and the second boding layer 36 is in the range of 250 μm to 270 μm, the diameter of the Cu core solder plated ball is 200 μm, and Ni plating in the range of approximately 0.5 μm to 2 μm, and the solder plating 34 having a thickness in the range of approximately 5 μm to 50 μm is coated thereon, a result of calculating which thickness is optimal is illustrated in FIG. 5.

When an optimal solder thickness range is acquired from an intersection point of a curve in which a vertical axis represents a volume and a horizontal axis represents a solder plating thickness before connection, and plotted by calculating the solder amount V2 of the solder plating 34 before connection, a curve to plot a ½ space volume when it is assumed that a space of approximately a half of a volume acquired by subtracting the Cu core volume from the hole space is occupied by a solder and an intermetal compound after connection and the remaining half of space is occupied by a resin that flows in from the periphery, and a curve to plot the ½ space volume when there is a clearance of 10 μm between the Cu core solder plated ball and the hole, the optimal solder thickness range is approximately 12 μm to 17 μm. The boards are integrally thermal-compressed by using the Cu core solder plated ball having the obtained solder plating thickness.

Referring back to the description of the process of FIG. 4F, a state in the drawing illustrates the coated solder of the Cu core solder plated ball formed with the optimal solder plating thickness is heated by the vacuum thermal-compression device to reach a solder melting temperature and starts being melted, and as a result, an intermetal compound of Sn and an electrode material and a remaining melted solder 40 are formed on the boundaries with the copper electrodes 32 and 38 in the drum shape. In this case, the resins of the first bonding material layer 31 and the second bonding material layer 36 are also in a melted state.

At the time when the heating temperature in the vacuum thermal-compression device reaches 230° C. which is targeted, when pressure which becomes hydrostatic pressure is applied to the entire upper second board 37 at timings illustrated in FIG. 6A to 6D, the melted bonding materials 36 and 31 flow into the void 39 of the hole space, and as a result, the void 39 is filled by the resin which is the bonding material as illustrated in FIG. 4G. The intermetal compound and the solder having the drum shape, which are formed around the Cu core ball 35 are covered with the resin which is the bonding material to prevent the position of the ball from deviating by contraction of the core layer 33, thereby maintaining the drum shape.

Further, like the control example of the temperature in the vacuum thermal-compression device of FIG. 6A, by maintaining the state of 230° C. for approximately 10 minutes, the solder (Sn) and Cu are sufficiently made into an intermetal compound at the boundaries of the melted solder of the Cu core solder plated ball and the copper electrodes 32 and 38 to prevent the solder from being melted in the board at the time of heating the bonded board of the embodiment, thereby forming a rigid connection portion.

As in the embodiment, on the bonding surface of each bonding target board, the electrode 25 that intends to achieve the electrical connection is prepared at a predetermined position in connection with an end of the through-hole 26, and as a result, interlayer connection of the electrodes facing each other is performed by the Cu core solder plated ball to thereby suppress generation of a non-conduction part of the through-hole serving as the stub.

The boards are integrally thermally-compressed by using the bonding process of the boards to implement the bonded board and the board wiring with low cost.

In the solder ball plating of the embodiment, Sn-based, SnAgCu-based, (low Ag-based), SnCu-based, SnBi-based, and SnZn-based Pb-free solders, and a Pb-containing solder may be used. Further, combinations such as only the Cu core ball, only Ni plating on the Cu core ball, direct solder plating on the Cu core ball, and the like may be used.

The core ball may be made of Ni, Al, Au, Pt, Pd, and the like and the core ball plated with Ni, Al, Au, Pt, and Pd may be used.

### Second Embodiment

In the embodiment, an example different from the first embodiment in the bonding process will be described.

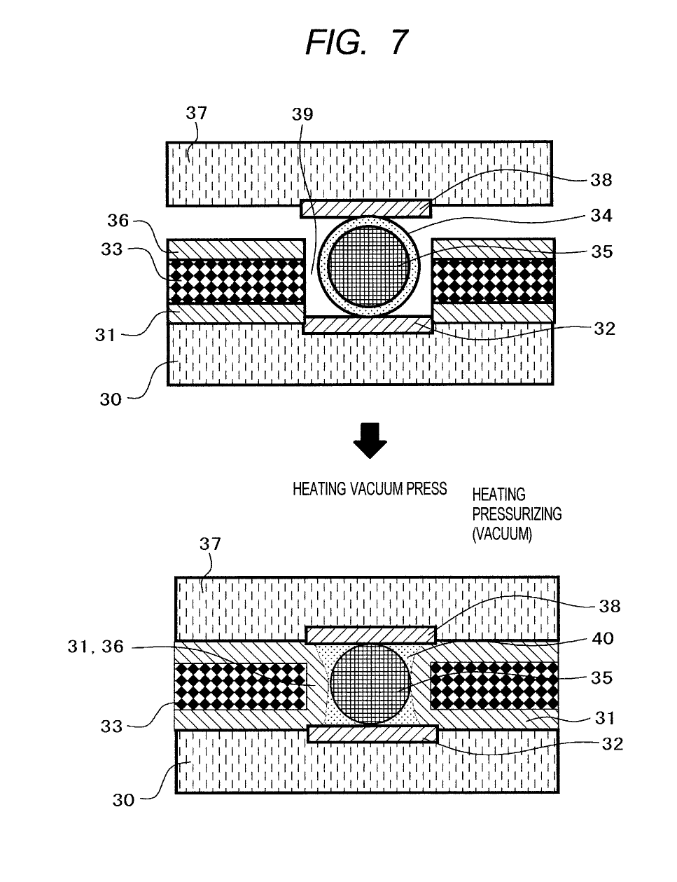

FIG. 7 is a diagram illustrating a schematically configured cross section of a Cu coreSn3Ag0.5Cu solder plated ball, three interlayer bonding material layers, and upper and lower printed boards constituting the bonding portion of the bonded board of the embodiment before and after vacuum thermal press.

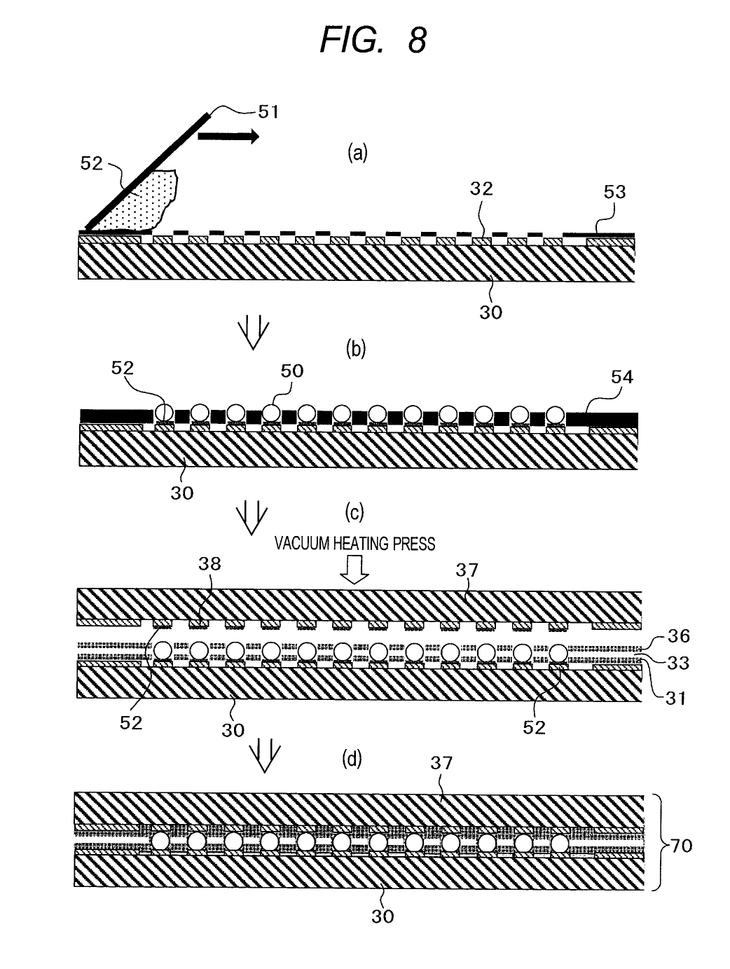

The bonded board of the embodiment is formed as follows according to a bonding process illustrated in FIG. 8.

(1) The electrode 32 for performing electrical connection between the upper and lower multilayered printed boards or a dummy electrode 32 for maintaining only a bonding strength is formed on the upper surface layer of the lower multilayered printed board 30 which is the bonding target as illustrated in FIG. 8A. By placing a printing mask 53 on the lower multilayered printed board 30, the flux (the flux may not be applied) and Sn3Ag0.5Cu solder paste 52 is applied to each electrode by a squeegee 51.

(2) After the printing mask 53 is removed, a mask 54 with a drilled hole for ball mounting is subsequently placed on the lower multilayered printed board 30 and the Cu core Sn3Ag0.5Cu solder plated ball is put in, and the ball is moved on the mask 54 by, for example, the brush, and the like and a Cu core Sn3Ag0.5Cu solder plated ball 50 is put in each hole of the mask 54 one by one as illustrated in FIG. 8B.

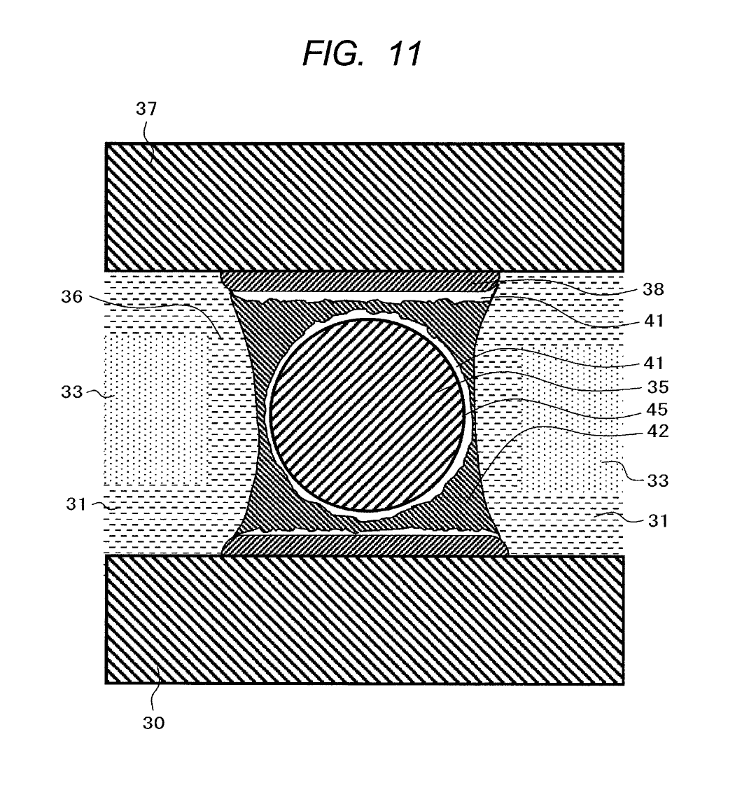

Subsequently, the solder of the Cu core Sn3Ag0.5Cu solder plated ball and the solder paste 52 printed on the electrode 32 are melted by reflow heating to connect the Cu core solder plated ball and the electrode 32 of the lower multilayered printed board 30 as illustrated in FIG. 10.

(3) Subsequently, the Cu core Sn3Ag0.5Cu solder plated ball is taken out from the reflow heating, the ball mounting mask 54 is removed, and the three interlayer bonding material layers are mounted on the lower multilayered printed board 30 as illustrated in FIG. 8C through holes of the respective three interlayer bonding material layers 31, 33, and 36 with the drilled hole for ball mounting with respect to the Cu core solder plated ball bonded to the electrode 22 of the lower multilayered printed wiring board 30.

In the three interlayer bonding material layers 31, 33, and 36, the first bonding material layer 31 is formed by, for example, the prepreg material (the material to be cured, which is acquired by impregnating an epoxy resin, and the like in the glass fiber), the core layer 33 is formed by, for example, the C stage (the glass fiber containing material in which the plastic material has already been cured), and the second bonding material layer 36 is formed by, for example, the prepreg material similarly. While the three interlayer bonding material layers are bonded and integrated in advance, the drilled holes for ball mounting are drilled on the three interlayer bonding material layers and thereafter, the three interlayer bonding material layers are mounted on the lower multilayered printed board 30 as described above.

Subsequently, the upper multilayered printed wiring board 37 is positioned and coated as illustrated in FIG. 8C. The flux (the flux may not be printed) and the solder paste 52 may be or not be printed on each electrode 38 of the upper multilayered printed wiring board 37.

(4) The board is pressed vertically by using a jig so that each electrode 38 of the upper multilayered printed wiring board 37 and the Cu core solder plated ball 50 contact each other. However, as described above, in the case of a large-sized board such as the midplane, and the like which is targeted in the embodiment, for example, when wiring density is high at the center, it is expected that the board has a ventricose shape, of which the center is swelled, due to a difference in linear expansion coefficient of the materials such as the resin and copper. In this case, when the board is vertically pressed in an initial stage, for example, a very small gap is generated between an upper solder 42 of the Cu core solder plated ball 35 and the solder paste 52 printed on the electrode 38 of the upper multilayered printed wiring board as illustrated in FIG. 10, in the electrodes on the peripheries of the upper and lower multilayered printed wiring boards that face each other.

(5) In this state, the board is put in the vacuum heating press device for each jig and the board is pressed lightly (approximately 1 to 5 kg/cm²) by pressure at which the upper solder 42 of the Cu core solder plated ball 35 and the solder paste 52 printed on the electrode 38 of the upper multilayered printed wiring board contact each other. A subsequent vacuum heating press condition is illustrated in FIGS. 6A to 6D. In the case of the embodiment, a vacuum press/thermal curing process is used when a composition of the used solder is Sn3Ag0.5Cu and a melting point (217° C.) of the solder is higher than a resin curing temperature (generally, 160° C. to 185° C.)

FIG. 6A is a mimetic diagram illustrating a temperature progress with respect to time.

FIG. 6B is a mimetic diagram illustrating thrust of press with respect to time.

FIG. 6C is a mimetic diagram illustrating pressure in a chamber with respect to time when the inside of the chamber receiving the board is in a vacuum state.

FIG. 6D is a mimetic diagram acquired by summarizing a diagram for temperature (a), thrust (b), and pressure (c) with one sheet.

(6) First, the chamber is subjected to vacuum processing (approximately 1 kPa) (P₁) and thereafter, heating starts. After the temperature is equal to or higher than the melting point of the Sn3Ag0.5Cu solder by gradually increasing the temperature, the temperature reaches a maximum temperature Tmax=230° C. (T₂) and thereafter, the press starts to fill the void 39 of the hole space with the interlayer bonding resins 31 and 36 at thrust F₁.

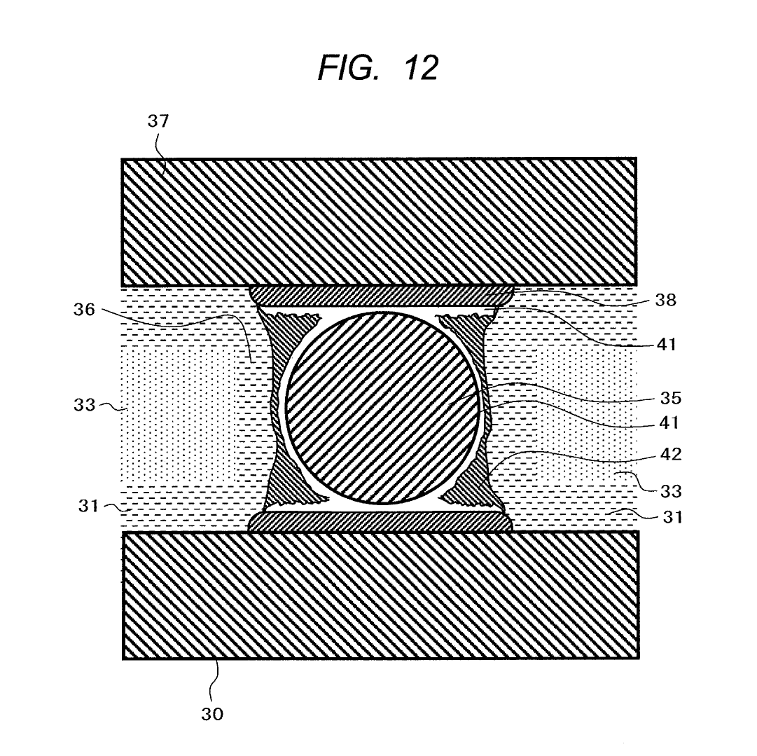

The solder paste 52 printed on the electrode 32 of the lower multilayered printed wiring board, the solder 42 of the Cu core solder plated ball 50, and the solder paste 52 printed on the electrode 38 of the upper multilayered printed wiring board are melted and connected while the heating temperature reaches a temperature which is equal to or higher than the melting point of the solder. Further, the solder paste 52 printed on the electrode 38 of the upper multilayered printed wiring board is melted to form a welcoming solder between the electrodes on the periphery of the board to be connected with the melted solder 42 of the Cu core solder plated ball 50, and as a result, the solder 42, and the intermetal compound 41 of Sn, and Cu, Ni, and an electrode material form the drum-shaped fillet between the electrodes 38 and 32 of the upper and lower multilayered printed wiring boards as illustrated in FIG. 11.

After the temperature is maintained for 10 minutes at 230° C. which is T₂:Tmax equal to or higher than the melting point of the solder, the temperature is decreased up to temperature T₁:185° C. which is the temperature suitable for the resin curing and maintained for a required time (for example, 45 minutes). Thereafter, the temperature of the chamber/jig is decreased up to an approximate room temperature and the pressure is returned to an atmospheric pressure to open the press. Each timing is illustrated in to FIG. 6D, and by considering a melting viscosity behavior of the interlayer bonding resins 31 and 36, the press preferably starts while flowability of the resin remains before the melting viscosity reaches a curing viscosity area of the resin (FIG. 8C).

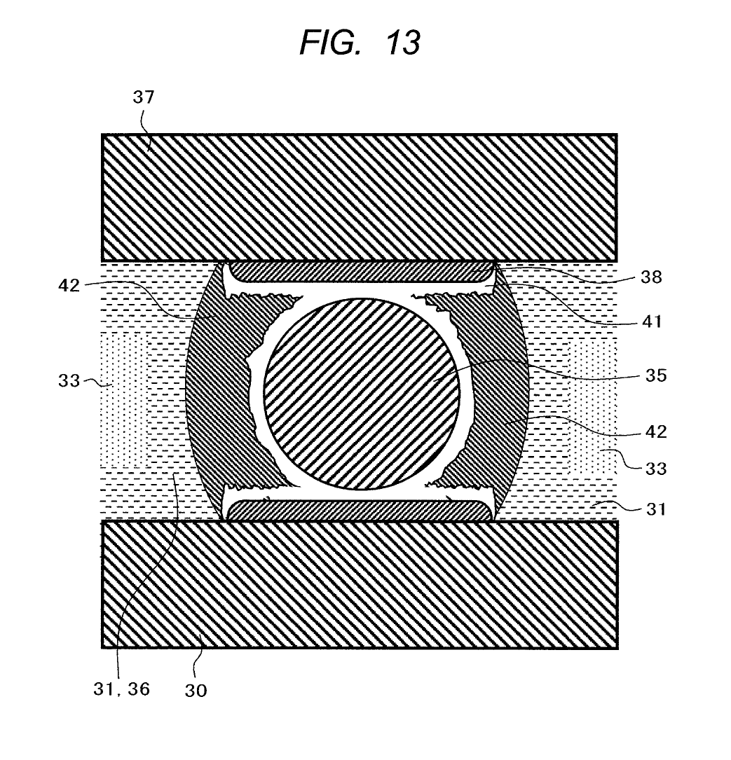

(7) The formed electrode part and the cross section of the board are in a lower part of FIG. 7. As illustrated in a profile (FIG. 6D) of the vacuum heating press used in the embodiment, a connection shape in the case in which timings of softening of a prepreg impregnated resin which is subjected to solder wetting/spreading and heating, and an inflow are excellent becomes a solder fillet shape having an excellent drum shape as illustrated in FIG. 12. Further, when the amount of the solder paste 52 is excessive, the connection shape illustrated in FIG. 13 is expected, but it is anticipated that a connection strength deteriorates as compared with the case of FIG. 12, and as a result, controlling the appropriate amount of the solder paste 52 is required.

While the position of the Cu core ball does not deviate from the position of the electrode of the board by using the core layer 33 for preventing the position of the Cu core ball from deviating, the Cu core ball is integrally and thermally compressed by using the bonding process of the board to implement a low-cost bonded board 70 (FIG. 8D).

In the embodiment, when the boards are solder-connected by integrally and thermally compressing the Cu core solder plated ball, a connection height between the boards may be determined as the height of a total of three layers of the bonding material layer, the core layer, and the bonding material layer. The height of the solder may be controlled by using the prepreg containing the glass fiber as the bonding material layer, and pressing pressure is not applied only to the solder ball but the balance of the whole bonding material layer is totally excellent and the solder connection height of the Cu core solder plated ball, that is, the distance between the boards may be controlled. A mechanism of controlling a cross section of the solder connection portion in the drum shape is as follows. The solder amount and the type of the flux are adjusted so that the solder is wet and spread to be larger than the diameter of the Cu core ball. After the solder is wet and spread, sufficient thrust F₁ is applied to the vacuum thermal press of the board, which is heated and the bonding material of the softened prepreg flows into a space around the ball which is solder-connected in the drum shape. In this case, the resin flows into the space by vacuum and the resin may be uniformly pressed onto the melted solder by the hydrostatic pressure. Meanwhile, a thermal linear expansion coefficient of the core layer is used, which is equivalent or close to a thermal linear expansion coefficient of the board to thereby prevent the position of the Cu core solder plated ball from deviating due to the contraction of the board. Likewise, connection for maintaining the solder connection shape having the drum shape which is highly reliable is integrally formed in a general printed plate forming process.

Further, the Cu core solder plated ball is, in advance, heated to form a Ni—Sn-based compound between an Ni layer and a solder layer and most solders are made into the compound by a subsequent bonded board forming process. When the temperature is increased to the solder melting point or more in reflow and flow soldering process at the time of mounting components on the bonded boards in the embodiment by this method, the temperature which the soldered part in the board is remelted and volume-expanded to enable preventing short-circuit by melting and soldering with a neighboring wiring or a neighboring Cu core solder plated ball.

In the solder ball plating of the embodiment, Sn-based, SnAgCu-based, (low Ag-based), SnCu-based, SnBi-based, and SnZn-based Pb-free solders, and a Pb-containing solder may be used. Further, combinations such as only the Cu core ball, only Ni plating on the Cu core ball, direct solder plating on the Cu core ball, and the like may be used.

The core ball may be made of Ni, Al, Au, Pt, Pd, and the like and the core ball plated with Ni, Al, Au, Pt, and Pd may be used.

### Third Embodiment

In the embodiment, an example in which solder having a different melting point from the second embodiment will be described.

FIG. 7 is a diagram illustrating a schematically configured cross section of a Cu core Sn58Bi solder plated ball, three interlayer bonding material layers, and upper and lower printed boards constituting the bonding portion of the bonded board of the embodiment before and after vacuum thermal press.

The bonded board of the embodiment is formed as follows according to a bonding process illustrated in FIG. 8.

(1) The electrode 32 for electrical connection between the upper and lower multilayered printed boards or a dummy electrode 32 for maintaining only a bonding strength is formed on the upper surface layer of the lower multilayered printed board 30 which is the bonding target as illustrated in FIG. 8A. By placing a printing mask 53 on the lower multilayered printed board 30, the flux and Sn58Bi solder paste 52 are applied to each electrode by the squeegee 51.

(2) After the printing mask 53 is removed, the mask 54 with the drilled hole for ball mounting is subsequently placed on the lower multilayered printed board 30 and the Cu core Sn58Bi solder plated ball is put in, and the ball is moved on the mask 54 by, for example, the brush, and the like and the Cu core Sn58Bi solder plated ball 50 is put in each hole of the mask 54 one by one as illustrated in FIG. 8B.

Subsequently, the solder of the Cu core Sn58BiCu solder plated ball and the solder paste 52 printed on the electrode 32 are melted by reflow heating to connect the Cu core solder plated ball and the electrode 32 of the lower multilayered printed board 30 as illustrated in FIG. 10.

(3) Subsequently, the Cu core Sn58BiCu solder plated ball is taken out from the reflow heating, the ball mounting mask 54 is removed, and the three interlayer bonding material layers are mounted on the lower multilayered printed board 30 as illustrated in FIG. 8C through holes of the respective three interlayer bonding material layers 31, 33, and 36 with the drilled hole for ball mounting with respect to the Cu core solder plated ball bonded to the electrode 22 of the lower multilayered printed wiring board 30.

In the three interlayer bonding material layers 31, 33, and 36, the first bonding material layer 31 is formed by, for example, the prepreg material (the material to be cured, which is acquired by impregnating an epoxy resin, and the like in the glass fiber), the core layer 33 is formed by, for example, the C stage (the glass fiber containing material in which the plastic material has already been cured), and the second bonding material layer 36 is formed by, for example, the prepreg material similarly. While the three interlayer bonding material layers are bonded and integrated in advance, the drilled holes for ball mounting are drilled on the three interlayer bonding material layers, and thereafter, the three interlayer bonding material layers are mounted on the lower multilayered printed board 30 as described above.

Subsequently, the upper multilayered printed wiring board 37 is positioned and coated as illustrated in FIG. 8C. The Sn58Bi solder paste 52 is, in advance, printed on each electrode 38 of the upper multilayered printed wiring board 37, the solder is melted by reflow heating, the welcoming solder is formed, and the formed welcoming solder is washed as necessary.

(4) The board is pressed vertically by using the jig so that the welcoming solder on each electrode 38 of the upper multilayered printed wiring board 37 and the Cu core solder plated ball 50 contact each other. However, as described above, in the case of a large-sized board such as the midplane, and the like which is targeted in the embodiment, for example, when wiring density is high at the center, it is expected that the board has a ventricose shape, of which the center is swelled, due to a difference in linear expansion coefficient of the materials such as the resin and copper. In this case, when the board is vertically pressed in an initial stage, for example, a very small gap is generated between an upper solder 42 of the Cu core solder plated ball 35 and the solder paste 52 printed on the electrode 38 of the upper multilayered printed wiring board as illustrated in FIG. 10, in the electrodes on the peripheries of the upper and lower multilayered printed wiring boards that face each other.

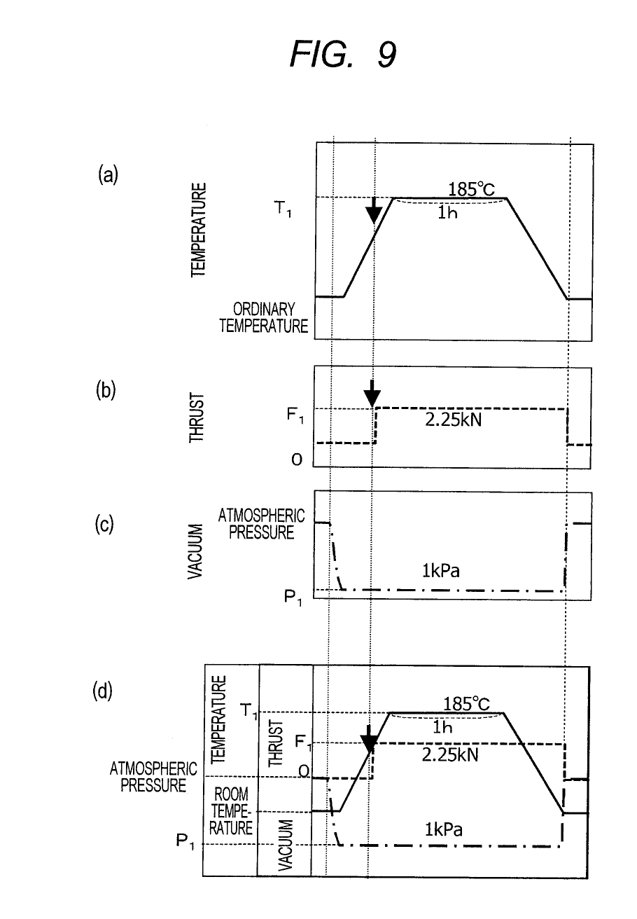

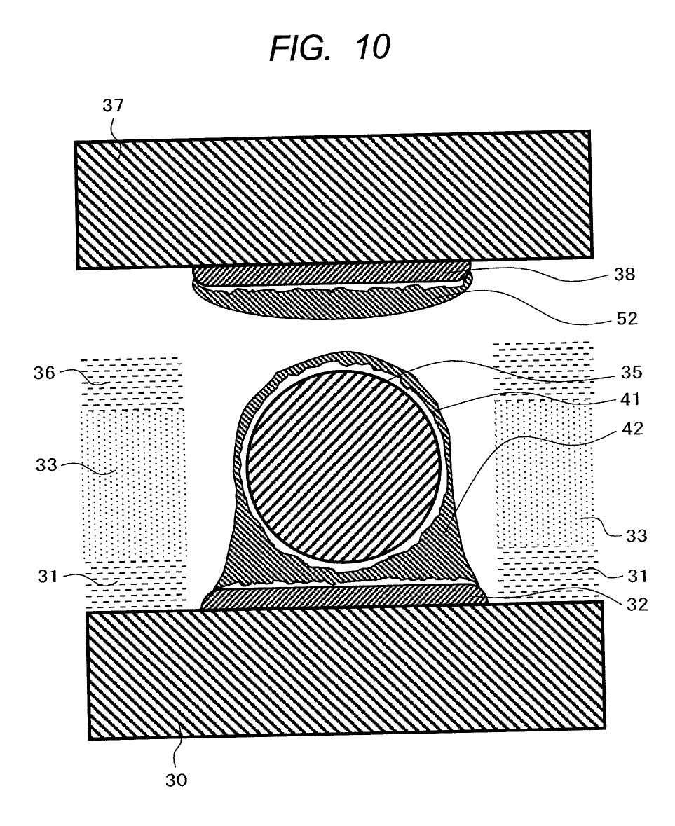

(5) In this state, the board is put in the vacuum heating press device for each jig and the board is pressed (approximately 1 to 5 kg/cm²) lightly by pressure at which the upper solder 42 of the Cu core solder plated ball 35 and the solder paste 52 printed on the electrode 38 of the upper multilayered printed wiring board contact each other. A subsequent vacuum heating press condition is illustrated in FIGS. 9A to 9D. In the case of the embodiment, a vacuum press/thermal curing process is used when a composition of the used solder is Sn58Bi and a melting point (138° C.) of the solder is lower than a resin curing temperature (generally, 160° C. to 185° C.)

FIG. 9A is a mimetic diagram illustrating a temperature progress with respect to time.

FIG. 9B is a mimetic diagram illustrating thrust of press with respect to time.

FIG. 9C is a mimetic diagram illustrating pressure in a chamber with respect to time when the inside of the chamber receiving the board is subjected to vacuum processing.

FIG. 9D is a mimetic diagram acquired by summarizing a diagram for temperature (a), thrust (b), and pressure (c) with one sheet.

(6) First, the chamber is subjected to vacuum processing (approximately 1 kPa) (P₁) and thereafter, heating starts. After the temperature is equal to or higher than the melting point of the Sn58Bi solder by gradually increasing the temperature, the press starts to fill the void 39 of the hole space with the interlayer bonding resins 31 and 36 at thrust F₁.

The solder paste 52 printed on the electrode 32 of the lower multilayered printed wiring board, the solder 42 of the Cu core solder plated ball 50, and the solder paste 52 printed on the electrode 38 of the upper multilayered printed wiring board are melted and connected while the heating temperature reaches a temperature which is equal to or higher than the melting point of the solder. Further, the solder paste 52 printed on the electrode 38 of the upper multilayered printed wiring board is melted to form a welcoming solder between the electrodes on the periphery of the board to be connected with the melted solder 42 of the Cu core solder plated ball 50, and as a result, the solder 42, and the intermetal compound 41 of Sn, and Cu, Ni, and an electrode material form the drum-shaped fillet between the electrodes 38 and 32 of the upper and lower multilayered printed wiring boards, as illustrated in FIG. 11.

Since the resin curing temperature T₁ is equal to or higher than the melting point of the solder, after the temperature is maintained at T₁:Tmax=185° C. for 1 hour, the temperature of the chamber/jig is decreased up to an approximate room temperature and the pressure is returned to an atmospheric pressure to open the press. Each timing is illustrated in FIG. 9D, and by considering a melting viscosity behavior of the interlayer bonding resins 31 and 36, the press preferably starts while flowability of the resin remains before the melting viscosity reaches a curing viscosity area of the resin (FIG. 8C).

(7) The formed electrode part and the cross section of the board are in a lower part of FIG. 7. As illustrated in a profile (FIG. 9D) of the vacuum heating press used in the embodiment, since the solder has already been wet/spread as the welcoming solder, a connection shape in the case in which timings of softening of a prepreg impregnated resin heated and an inflow are excellent becomes a solder fillet shape having an excellent drum shape as illustrated in FIG. 12.

While the position of the Cu core ball does not deviate from the position of the electrode of the board by using the core layer 33 for preventing the position of the Cu core ball from deviating, the board is integrally and thermally compressed by using the bonding process of the board to implement a low-cost board wiring 70 (FIG. 8D).

In the solder ball plating of the embodiment, Sn-based, SnAgCu-based, (low Ag-based), SnCu-based, SnBi-based, and SnZn-based Pb-free solders, and a Pb-containing solder may be used. Further, combinations such as only the Cu core ball, only Ni plating on the Cu core ball, direct solder plating on the Cu core ball, and the like may be used.

The core ball may be made of Ni, Al, Au, Pt, Pd, and the like and the core ball plated with Ni, Al, Au, Pt, and Pd may be used. As the composition of the solder plate, Pb-free solder or Pb-containing solder may be used as necessary, in addition to Sn-based, SnAgCu-based, (low Ag-based), SnCu-based, SnBi-based, and SnZn-based solders.

What is claimed is:

1. A manufacturing method of a bonded board, comprising:
mounting a first bonded board on a base with a surface thereof where an electrode is formed, facing the top;
sequentially mounting a first bonding material layer and a core layer on the first bonded board with opened holes matched with the positions of the electrodes;
putting and placing a Cu core solder plated ball coated with a predetermined thickness one by one in the opened hole of the core layer;
mounting a second bonding material layer on the core layer with the opened hole matched with the position of the electrode;
mounting a second bonded board at a position where the electrode formed on the first bonded board and an electrode of the second bonded board face each other with a surface where the electrode is formed, facing the bottom; and
uniformly heating the first and second bonded boards, the first and second bonding material layers, the core layer, and the Cu core solder plated ball which are overlapped with each other and uniformly applying thrust to the entire second bonded board to integrally and thermally compress the first and second bonded boards, the first and second bonding material layers, the core layer, and the Cu core solder plated ball, under an environment in which the first and second bonded boards, the first and second bonding material layers, the core layer, and the Cu core solder plated ball are put in a vacuum thermal compression device to be subjected to vacuum processing.

2. The manufacturing method of a bonded board according to claim 1, wherein:
in the uniformly heating of the first and second bonded boards, the first and second bonding material layers, the core layer, and the Cu core solder plated ball which are overlapped with each other and uniformly applying thrust to the entire second bonded board to integrally and thermally compress the first and second bonded boards, the first and second bonding material layers, the core layer, and the Cu core solder plated ball, under a vacuum processing environment in which the first and second bonded boards, the first and second bonding material layers, the core layer, and the Cu core solder plated ball are put in a vacuum thermal compression device to be subjected to vacuum processing,
melted resins of the first and second bonding material layers flow into a hole space between the electrodes to cover a solder connection portion of the Cu core ball and a control of decreasing and maintaining the temperature in the device to a predetermined temperature or a second predetermined temperature is performed until reaching curing viscosity, by applying uniform thrust to the entire second bonded board, while maintaining the temperature at the predetermined temperature at the time when the temperature reaches the predetermined temperature which is higher than a melting point of solder by uniform heating under the vacuum processing environment.

3. The manufacturing method of a bonded board according to claim 1, wherein the Cu core solder plated ball and solder of the solder paste are Sn-based, SnAgCu-based, SnCu-based, SnBi-based, and SnZn-based Pb-free solders, or Pb-containing solder.

4. The manufacturing method of a bonded board according to claim 1, wherein the Cu core solder plated ball is any one of only a Cu core ball, only Ni plating on the Cu core ball, solder plating on the Ni plating on the Cu core ball, and direct solder plating on the Cu core ball, or is formed any one of Ni, Al, Au, Pt, and Pd instead of the Cu core ball, or plating any one of Ni, Al, Au, Pt, and Pd on the Cu core ball.

5. A manufacturing method of a bonded board, comprising:
applying solder paste to an electrode formed on a bonding surface of a first bonded board;
putting and placing a Cu core solder plated ball coated with a predetermined thickness one by one in a hole opened on a mask mounted on the bonded board in each electrode of the first bonded board of each electrode of the first bonded board;
connecting a Cu core ball and the electrode of the first bonded board by melting solder of the Cu core solder plated ball and solder paste applied to the electrode by reflow heating;
mounting on the first bonded board a layer associated with bonding of three layers constituted by a core layer where a hole determining the position of the Cu core solder plated ball is formed, and first and second bonding material layers having holes formed at the same position and placed on both surfaces of the core layer, which bond the core layer and the bonded board, by passing the Cu core solder plated ball connected onto the electrode of the first bonded board through the hole;
mounting a second bonded board at a position where the electrode formed on the first bonded board and an electrode of the second bonded board face each other with a surface where the electrode is formed, facing the bottom; and
uniformly heating the first and second bonded boards, the first and second bonding material layers, the core layer, and the Cu core solder plated ball which are overlapped with each other and uniformly applying thrust to the entire second bonded board to integrally and thermally compress the first and second bonded boards, the first and second bonding material layers, the core layer, and the Cu core solder plated ball, under an environment in which the first and second bonded boards, the first and second bonding material layers, the core layer, and the Cu core solder plated ball are put in a vacuum thermal compression device to be subjected to vacuum processing.

6. The manufacturing method of a bonded board according to claim 5, wherein:
in the uniformly heating of the first and second bonded boards, the first and second bonding material layers, the core layer, and the Cu core solder plated ball which are overlapped with each other and uniformly applying thrust to the entire second bonded board to integrally and thermally compress the first and second bonded boards, the first and second bonding material layers, the core layer, and the Cu core solder plated ball, under a vacuum processing environment in which the first and second bonded boards, the first and second bonding material layers, the core layer, and the Cu core solder plated ball are put in a vacuum thermal compression device to be subjected to vacuum processing,
melted resins of the first and second bonding material layers flow into a hole space between the electrodes to cover a solder connection portion of the Cu core ball and a control of decreasing and maintaining the temperature in the device to a predetermined temperature or a second predetermined temperature is performed until reaching curing viscosity, by applying uniform thrust to the entire second bonded board, while maintaining the temperature at the predetermined temperature at the time when the temperature reaches the predetermined temperature which is higher than a melting point of solder by uniform heating under the vacuum processing environment.

7. The manufacturing method of a bonded board according to claim 5, wherein the Cu core solder plated ball and solder of the solder paste are Sn-based, SnAgCu-based, SnCu-based, SnBi-based, and SnZn-based Pb-free solders, or Pb-containing solder.

8. The manufacturing method of a bonded board according to claim 5, wherein the Cu core solder plated ball is any one of only a Cu core ball, only Ni plating on the Cu core ball, solder plating on the Ni plating on the Cu core ball, and direct solder plating on the Cu core ball, or is formed any one of Ni, Al, Au, Pt, and Pd instead of the Cu core ball, or plating any one of Ni, Al, Au, Pt, and Pd on the Cu core ball.

9. A bonded board, comprising:
a layer which is associated with bonding of a three-layer structure constituted by a core layer having a hole for determining the position of a Cu core solder plated ball for connecting electrodes to each other between both boards of a first bonded board where one or more electrodes are formed on a first surface and a second bonded board where one or more electrodes are formed on a second surface with corresponding electrodes facing each other, and a plurality of bonding material layers having holes formed at the same position and placed on both surfaces of the core layer, which bonds the core layer and the bonded board; and
a Cu core solder plated ball placed between the electrodes one by one and the first surface of the first bonded board and the second surface of the second bonded board are bonded by an integral thermal-compression process,
wherein the Cu core ball is connected with the respective corresponding electrodes of both the bonded boards by a drum-shaped bonding portion constituted by solder and an intermetal compound, and
resins of the plurality of bonding material layers are melted by the integral thermal compression process and fills a void around the drum-shaped bonding portion constituted by the solder and the intermetal compound connecting the Cu core ball and each electrode to become a cured bonding material layer.

10. The bonded board according to claim 9, wherein the solder of the Cu core solder plated ball is Sn-based, SnAgCu-based, SnCu-based, SnBi-based, and SnZn-based Pb-free solders, or Pb-containing solder.

11. The bonded board according to claim 9, wherein the Cu core solder plated ball is any one of only a Cu core ball, only Ni plating on the Cu core ball, solder plating on the Ni plating on the Cu core ball, and direct solder plating on the Cu core ball, or any one of Ni, Al, Au, Pt, and Pd instead of the Cu core ball, or plating any one of Ni, Al, Au, Pt, and Pd on the Cu core ball.
